(19) United States
(12) Patent Application Publication
(10) Pub. No.: US 2026/0047480 A1
(43) Pub. Date: Feb. 12, 2026

(54) POWER CHIP PACKAGE STRUCTURE

(71) Applicant: TONG HSING ELECTRONIC INDUSTRIES, LTD., Taoyuan City (TW)

(72) Inventors: Yu-Te Hsieh, Taoyuan City (TW); ZZU-CHI CHIU, Taoyuan City (TW); YAN-WEI CHEN, Taoyuan City (TW)

(21) Appl. No.: 18/929,572

(22) Filed: Oct. 28, 2024

(30) Foreign Application Priority Data
Aug. 9, 2024 (TW) 113129865

(51) Int. Cl. H01L 23/29; H01L 23/00; H01L 23/31; H01L 23/64

(52) U.S. Cl. CPC H01L 23/298; H01L 23/3135; H01L 23/647; H01L 24/32; H01L 24/37; H01L 2224/32227; H01L 2224/32245; H01L 2224/3702; H01L 2924/3841

(57) ABSTRACT

A power chip package structure includes a power chip, a first transmission member, and at least two second transmission members, an encapsulant, and a diamond-like carbon (DLC) layer. The first transmission member and the at least two second transmission members are connected to the power chip. The power chip, the first transmission member, and the at least two second transmission members are embedded in the encapsulant. The encapsulant has a layout surface that is coplanar with a first end surface of the first transmission member and a second end surface of each of the at least two second transmission members. The DLC layer is formed on the layout surface with terminals. The DLC layer surrounds the first end surface to jointly form a first solder-receiving slot, and the DLC layer surrounds each of the two second end surfaces to jointly form a second solder-receiving slot.

### CROSS-REFERENCE TO RELATED PATENT APPLICATION

This application claims the benefit of priority to Taiwan Patent Application No. 113129865, filed on Aug. 9, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a package structure, and more particularly to a power chip package structure.

### BACKGROUND OF THE DISCLOSURE

Safety regulations of a conventional power chip package structure include a creepage distance and a clearance distance, and the conventional power chip package structure needs to meet requirements for one of the two distances, whichever is more stringent. This leads to subtle increases in costs and package size associated with the structural design of the conventional power chip package structure.

### SUMMARY OF THE DISCLOSURE

In response to the above-referenced technical inadequacies, the present disclosure provides a power chip package structure for effectively improving on the issues associated with conventional power chip package structures.

In order to solve the above-mentioned problems, one of the technical aspects adopted by the present disclosure is to provide a power chip package structure, which includes a power chip, a first transmission member, at least two second transmission members, an encapsulant, and a diamond-like carbon (DLC) layer. The power chip includes a chip body, a first bonding pad, and at least two second bonding pads. The chip body has a first surface and a second surface that is opposite to the first surface. The first bonding pad is formed on the first surface. The at least two second bonding pads are formed on the second surface and are spaced apart from each other. The first transmission member is connected to the first bonding pad. The first transmission member has a first end surface that is arranged away from the first bonding pad. The at least two second transmission members are respectively connected to the at least two second bonding pads. Each of the at least two second transmission members has a second end surface that is arranged away from the corresponding second bonding pad. The power chip, the first transmission member, and the at least two second transmission members are embedded in the encapsulant. The encapsulant has a layout surface that is coplanar with the first end surface of the first transmission member and the second end surfaces of the at least two second transmission members. The DLC layer is formed on the layout surface. The DLC layer surrounds the first end surface to jointly define a first solder-receiving slot, and the DLC layer surrounds each of the two second end surfaces to jointly define a second solder-receiving slot. The first end surface is spaced apart from an adjacent one of the two second end surfaces by a clearance distance that is defined along the first solder-receiving slot, the corresponding second solder-receiving slot, and a part of an outer end surface of the DLC layer.

In order to solve the above-mentioned problems, another one of the technical aspects adopted by the present disclosure is to provide a power chip package structure, which includes a power chip, a first transmission member, at least two second transmission members, an encapsulant, and a diamond-like carbon (DLC) layer. The power chip includes a chip body, a first bonding pad, and at least two second bonding pads. The chip body has a first surface and a second surface that is opposite to the first surface. The first bonding pad is formed on the first surface. The at least two second bonding pads are formed on the second surface and are spaced apart from each other. The first transmission member is connected to the first bonding pad. The first transmission member has a first end surface that is arranged away from the first bonding pad. The at least two second transmission members are respectively connected to the two at least second bonding pads. Each of the at least two second transmission members has a second end surface that is arranged away from the corresponding second bonding pad. The power chip, the first transmission member, and the at least two second transmission members are embedded in the encapsulant. The encapsulant has a layout surface and at least one slot that is recessed in the layout surface. A part of the first transmission member and a part of each of the at least two second transmission members are arranged in the at least one slot. The DLC layer is formed in the at least one slot and surrounds the part of the first transmission member and the part of each of the at least two second transmission members. An outer end surface of the DLC layer is coplanar with the first end surface and the two second end surfaces. The first end surface is spaced apart from an adjacent one of the two second end surfaces by a clearance distance that is defined along a part of the outer end surface of the DLC layer.

Therefore, the power chip package structure of the present disclosure is provided with the DLC layer that has no carbonization issue and that is cooperated with the first end surface and the two second end surfaces, such that the power chip package structure only needs to meet requirements of the clearance distance and does not need to consider a creepage distance, thereby reducing limitations on the structural design of the power chip package structure.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective view of a power chip package structure according to a first embodiment of the present disclosure;

FIG. 2 is a schematic cross-sectional view taken along line II-II of FIG. 1;

FIG. 3 is a schematic cross-sectional view of the power chip package structure according to a second embodiment of the present disclosure;

FIG. 4 is a schematic perspective view of the power chip package structure according to a third embodiment of the present disclosure;

FIG. 5 is a schematic cross-sectional view taken along line V-V of FIG. 4;

FIG. 6 is a schematic cross-sectional view showing the power chip package structure in another configuration according to the third embodiment of the present disclosure;

FIG. 7 is a schematic perspective view of the power chip package structure according to a fourth embodiment of the present disclosure;

FIG. 8 is a schematic cross-sectional view taken along line VIII-VIII of FIG. 7;

FIG. 9 is a schematic cross-sectional view showing the power chip package structure in another configuration according to the fourth embodiment of the present disclosure; and

FIG. 10 is a schematic cross-sectional view showing the power chip package structure in yet another configuration according to the fourth embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

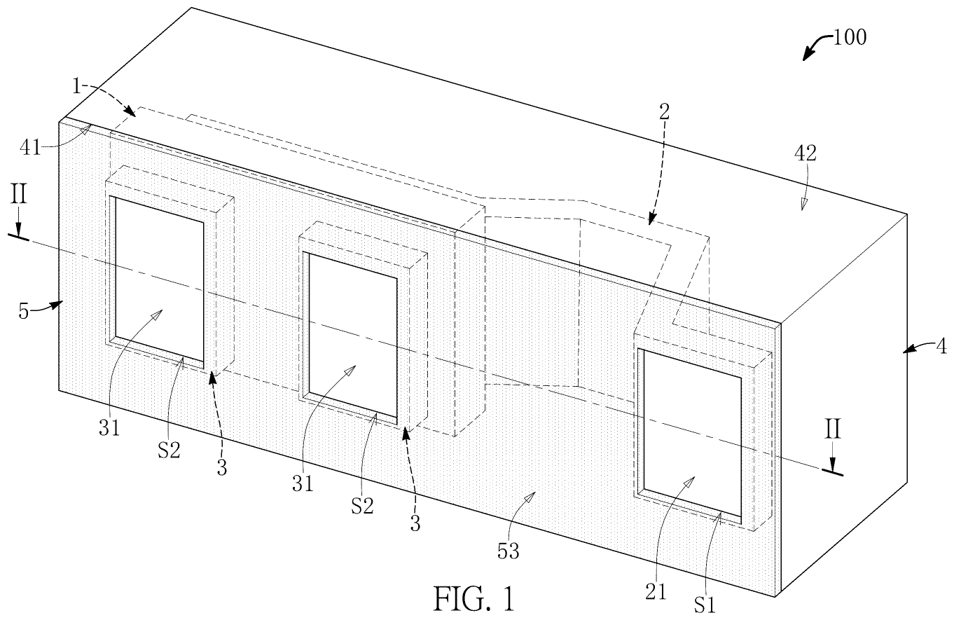

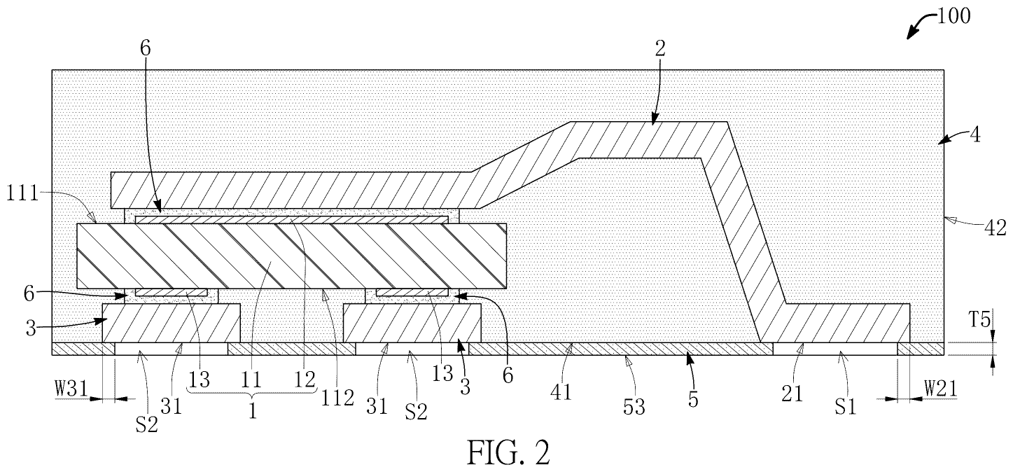

Referring to FIG. 1 and FIG. 2, a first embodiment of the present disclosure provides a power chip package structure 100 that preferably has a wire-less configuration. For example, the power chip package structure 100 can have a dual flat no-lead (DFN) package configuration or a quad flat no-lead (QFN) package configuration or discrete flat no-lead package in general, but the present disclosure is not limited thereto.

The power chip package structure 100 in the present embodiment includes a power chip 1, a first transmission member 2 connected to one side of the power chip 1, two second transmission members 3 connected to another side of the power chip 1, an encapsulant 4 embedding the above components therein, and a diamond-like carbon (DLC) layer 5 that is formed on the encapsulant 4.

The power chip 1 includes a chip body 11, a first bonding pad 12 formed on one side of the chip body 11, and two second bonding pads 13 that are formed on another side of the chip body 11. In the present embodiment, the chip body 11 has a first surface 111 and a second surface 112 that is opposite to the first surface 111. The first bonding pad 12 is formed on the first surface 111 and can be a drain pad, the two second bonding pads 13 are formed on the second surface 112 and are spaced apart from each other, and the two second bonding pads 13 can be a source pad and a gate pad, but the present disclosure is not limited thereto. For example, an arrangement of the two second bonding pads 13 can be adjusted or changed according to practical requirements and is not limited by the drawings; or, a quantity of the two second transmission members 3 can be at least two, and a quantity of components (e.g., the second bonding pads 13) corresponding to the second transmission members 3 is also at least two.

It should be noted that a type of the power chip 1 can be adjusted or changed according to practical requirements. For example, the power chip 1 can be an insulated gate bipolar transistor (IGBT), a power metal- oxide-semiconductor field-effect transistor (MOSFET), a bipolar junction transistor (BJT), a silicon carbide (SiC) power component, a gallium nitride (GaN) power component, a high electron mobility transistor (HEMT), or a fast recovery diode (FRD).

The first transmission member 2 is connected to the first bonding pad 12, and the first transmission member 2 has a first end surface 21 that is arranged away from the first bonding pad 12. The two second transmission members 3 are respectively connected to the two second bonding pads 13, and each of the two second transmission members 3 has a second end surface 31 that is arranged away from the corresponding second bonding pad 13. There could be more than two of transmission members 3 possibly based on the functionality of power chip 1, and there could be more than two of bond pads corresponding transmission members 3.

It should be noted that the power chip package structure 100 in the present embodiment includes a plurality of conductive pastes 6, e.g. Sintered silver (Ag) paste or solder paste. The first transmission member 2 is electrically bonded (e.g., sintered) to the first bonding pad 12 through one of the conductive pastes 6, and each of the two second transmission members 3 is electrically bonded (e.g., sintered) to the corresponding second bonding pad 13 through one of the conductive pastes 6, but the present disclosure is not limited thereto.

In the present embodiment, the first transmission member 2 is a lead frame, one end of the lead frame has the first end surface 21, and another end of the lead frame is connected to the first bonding pad 12. Moreover, each of the two second transmission members 3 is a metal block, and the two second transmission members 3 are respectively connected to the two second bonding pads 13, but the present disclosure is not limited thereto.

The power chip 1, the first transmission member 2, and the two second transmission members 3 are embedded in the encapsulant 4 and only enable the first end surface 21 and the two second end surfaces 31 to be exposed from the encapsulant 4, but the present disclosure is not limited thereto.

Specifically, the encapsulant 4 in the present embodiment is substantially a rectangular block and has a layout surface 41 (i.e., a bottom surface of the encapsulant 4) being a flat shape and an outer surface 42 that is connected to a peripheral edge of the layout surface 41. The first end surface 21 and the two second end surfaces 31 are exposed from the layout surface 41, and the layout surface 41 can be substantially coplanar with the first end surface 21 and the two second end surfaces 31. Moreover, the power chip 1, the first transmission member 2, and the two second transmission members 3 are located in a region (or a space) surrounded by the outer surface 42 of the encapsulant 4.

The DLC layer 5 is formed on the layout surface 41, and the DLC layer 5 in the present embodiment covers an entirety of the layout surface 41 of the encapsulant 4 and can be formed in a physical vapor deposition or chemical vapor deposition manner (e.g., an evaporation manner), but the present disclosure is not limited thereto. Moreover, a thickness of the DLC layer 5 is preferably within a range from 3 μm to 20 μm, and a resistivity of the DLC layer 5 is greater than 10¹⁰ ohm-cm, thereby enabling the DLC layer 5 to have a good insulation and heat-dissipation effect.

Moreover, the DLC layer 5 surrounds the first end surface 21 to jointly define a first solder-receiving slot S1, and the DLC layer 5 surrounds each of the two second end surfaces 31 to jointly define a second solder-receiving slot S2. In other words, the first end surface 21 is a bottom of the first solder-receiving slot S1, and the two second end surfaces 31 are bottoms of the two second solder-receiving slots S2, respectively. Specifically, the DLC layer 5 covers a peripheral region of the first end surface 21 (i.e., except for the first solder-receiving slot S1, all other regions of the first end surface 21 are covered by the DLC layer 5) that has a width W21 (i.e., an overlapped distance of the first end surface 21 and the DLC layer 5) being within a range from 5 μm to 100 μm. Moreover, the DLC layer 5 covers a peripheral region of each of the two second end surfaces 31 (i.e., except for the two second solder-receiving slots S2, all other regions of the two second end surfaces 31 are covered by the DLC layer 5) that has a width W31 (i.e., an overlapped distance of each of the two second end surfaces 31 and the DLC layer 5) being within a range from 5 μm to 100 μm.

Accordingly, the first transmission member 2 and the two second transmission members 3 can rapidly dissipate heat through the DLC layer 5, and when the power chip package structure 100 is soldered onto a circuit board to allow the first solder-receiving slot S1 and the two second solder-receiving slots S2 to accommodate solders (not shown in the drawings), the DLC layer 5 can not only increase wetting areas of the solders, but also forms protection walls on lateral sides of the solders that are formed with intermetallic compound (IMC), thereby preventing the IMC from having stress concentration and cracks for effectively improving product yield and reliability of the power chip package structure 100.

In summary, the first end surface 21 is spaced apart from an adjacent one of the two second end surfaces 31 by a clearance distance that is defined along the first solder-receiving slot S1, the corresponding second solder-receiving slot S2, and a part of an outer end surface 53 (or a bottom surface) of the DLC layer 5 (e.g., the outer end surface 53 is a surface of the DLC layer 5 arranged away from the power chip 1). Accordingly, the power chip package structure 100 of the present embodiment is provided with the DLC layer 5 that has no carbonization issue and that is cooperated with the first end surface 21 and the two second end surfaces 31, such that the power chip package structure 100 only needs to meet requirements of the clearance distance and does not need to consider creepage distance, thereby reducing limitations of the structural design of the power chip package structure.

### Second Embodiment

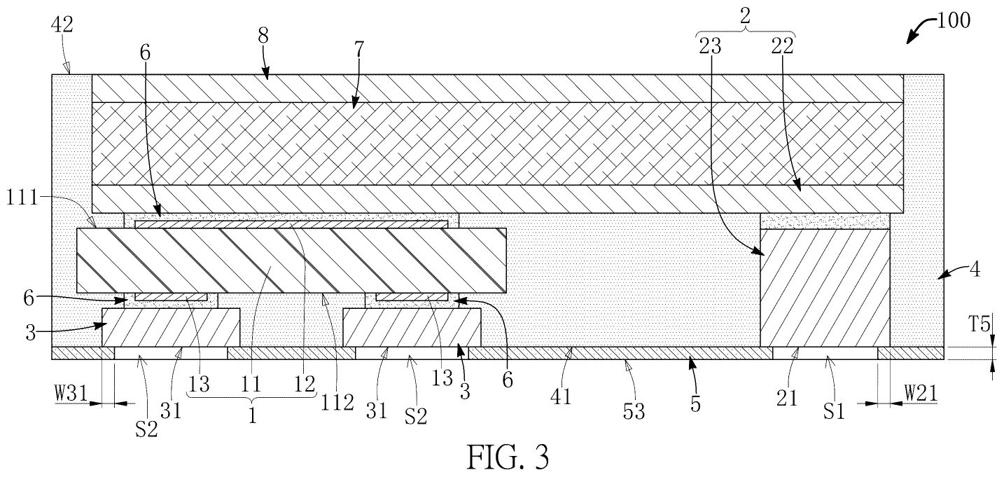

Referring to FIG. 3, a second embodiment of the present disclosure, which is similar to the first embodiment of the present disclosure, is provided. For the sake of brevity, descriptions of the same components in the first and second embodiments of the present disclosure will be omitted herein, and the following description only discloses different features between the first and second embodiments.

In the present embodiment, the power chip package structure 100 further includes a ceramic board 7 embedded in the encapsulant 4, an inner metal layer 22 formed on the ceramic board 7, and an extending metal block 23 that is connected to one end of the inner metal layer 22. The inner metal layer 22 and the extending metal block 23 are jointly defined as the first transmission member 21, the extending metal block 23 has the first end surface 21, and another end of the extending metal block 23 is connected to the first bonding pad 12.

Moreover, the power chip package structure 100 further includes an outer metal layer 8. The inner metal layer 22 and the outer metal layer 8 are respectively sintered to two opposite surfaces of the ceramic board 7, and a surface of the outer metal layer 8 arranged away from the inner metal layer 22 is preferably exposed from the encapsulant 4.

It should be noted that the inner metal layer 22 and the outer metal layer 8 in the present embodiment are respectively formed on the ceramic board 7 in a direct bond copper (DBC) manner, a direct plated copper (DPC) manner, or an active metal brazing (AMB) manner according to practical requirements, but the present disclosure is not limited thereto.

### Third Embodiment

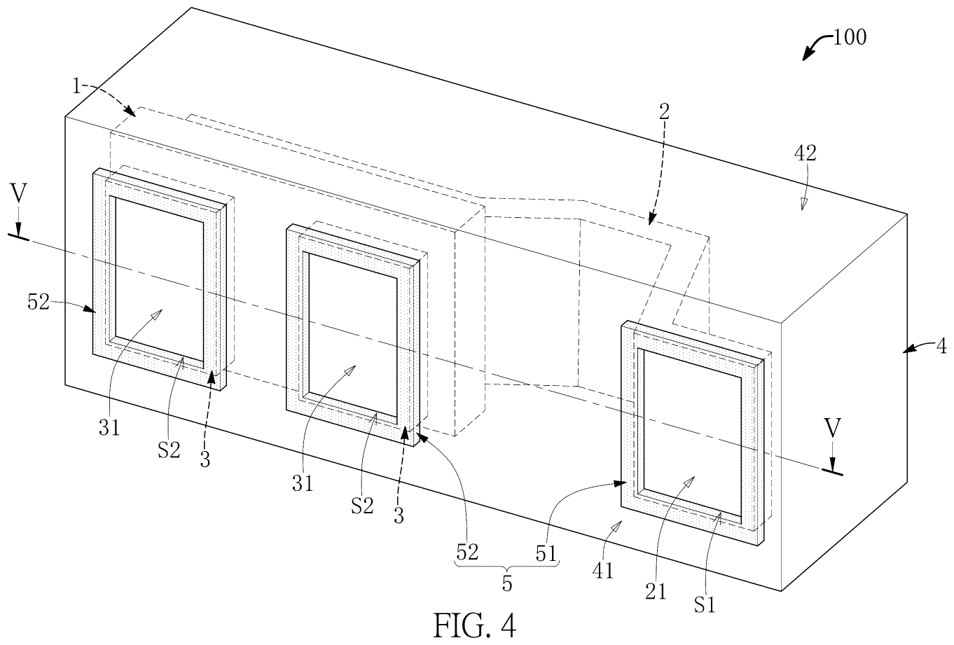

Referring to FIG. 4 to FIG. 6, a third embodiment of the present disclosure, which is similar to the first embodiment of the present disclosure, is provided. For the sake of brevity, descriptions of the same components in the first and third embodiments of the present disclosure will be omitted herein, and the following description only discloses different features between the first and third embodiments.

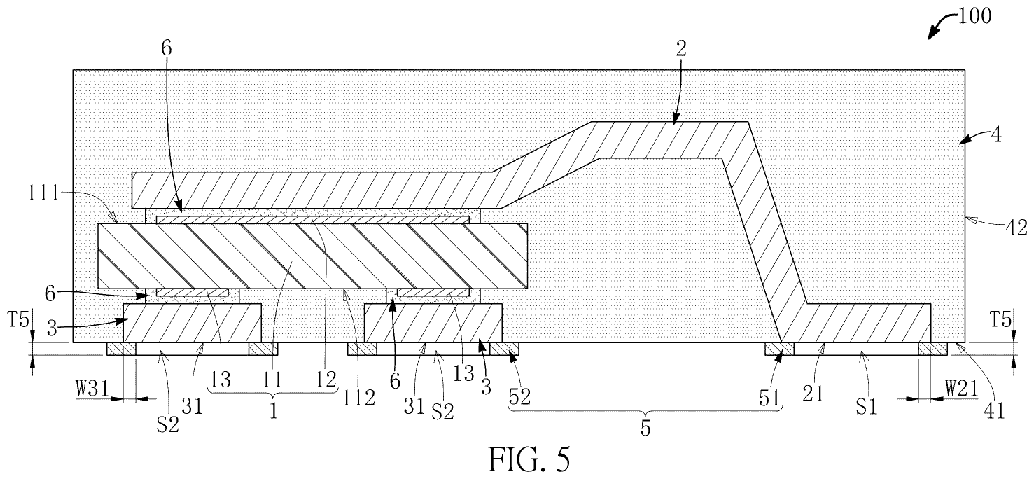

As shown in FIG. 4 and FIG. 5, the DLC layer 5 in the present embodiment includes a first ring 51 and two second rings 52 that are spaced apart from each other and that are spaced apart from the first ring 51. The first ring 51 surrounds the first end surface 21 to jointly define a first solder-receiving slot S1, and each of the two second rings 52 surrounds one of the two second end surfaces 31 to jointly define a second solder-receiving slot S2. Each of the first ring 51 and the two second rings 52 has a thickness T5 being within a range from 3 μm to 20 μm.

The first ring 51 covers a peripheral region of the first end surface 21 that has a width W21 being within a range from 5 μm to 100 μm, and each of the two second rings 52 covers a peripheral region of a corresponding one of the two second end surfaces 31 that has a width W31 being within a range from 5 μm to 100 μm, but the present disclosure is not limited thereto.

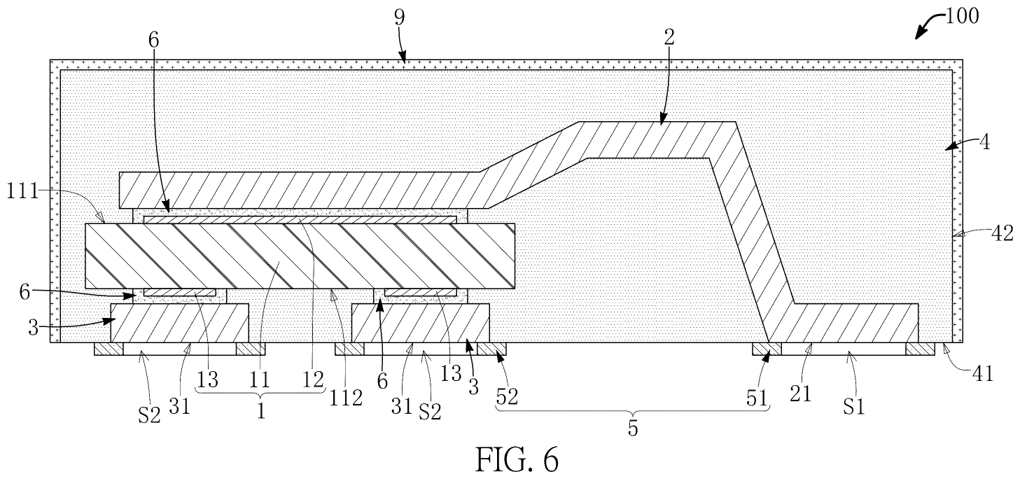

In addition, as shown in FIG. 6, the power chip package structure 100 further includes an electrical protection layer 9 that is formed on the outer surface 42 of the encapsulant 4 and that is made of a DLC material. The electrical protection layer 9 covers an entirety of the outer surface 42 and is not in contact with the DLC layer 5, and a resistivity of the electrical protection layer 9 is less than a resistivity of the DLC layer 5. In the present embodiment, the resistivity of the electrical protection layer 9 is preferably less than 10¹⁰ ohm-cm, and a resistivity of the DLC layer 5 is preferably greater than 10¹⁰ ohm-cm.

Accordingly, the power chip package structure 100 in the present embodiment is provided with an electro-static discharge (ESD) protection function and an electromagnetic interference (EMI) protection function by forming the electrical protection layer 9, thereby meeting more electrical requirements.

### Fourth Embodiment

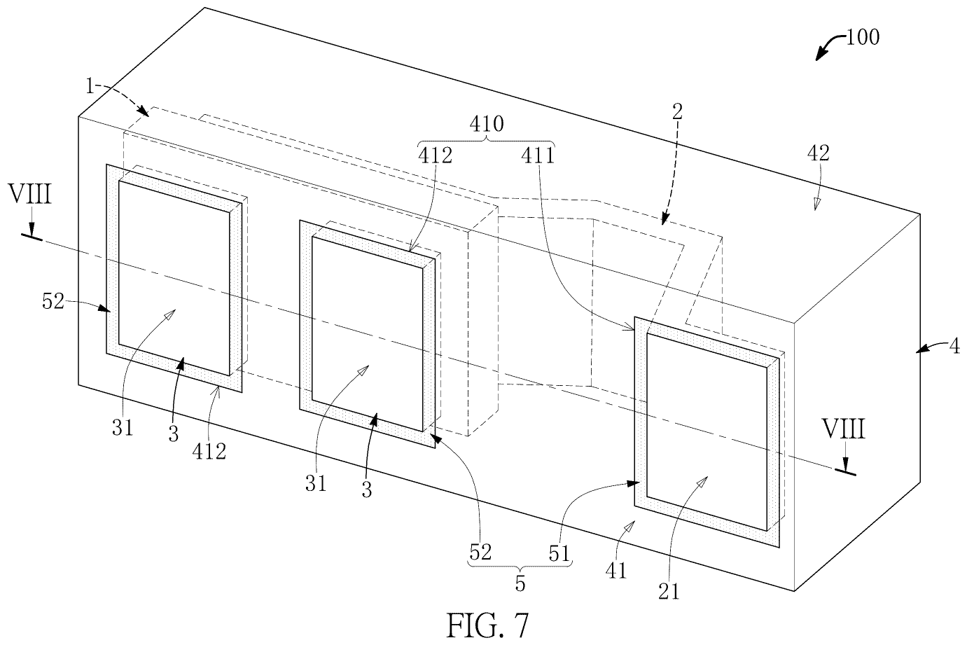

Referring to FIG. 7 to FIG. 10, a fourth embodiment of the present disclosure, which is similar to the first embodiment of the present disclosure, is provided. For the sake of brevity, descriptions of the same components in the first and fourth embodiments of the present disclosure will be omitted herein, and the following description only discloses different features between the first and fourth embodiments.

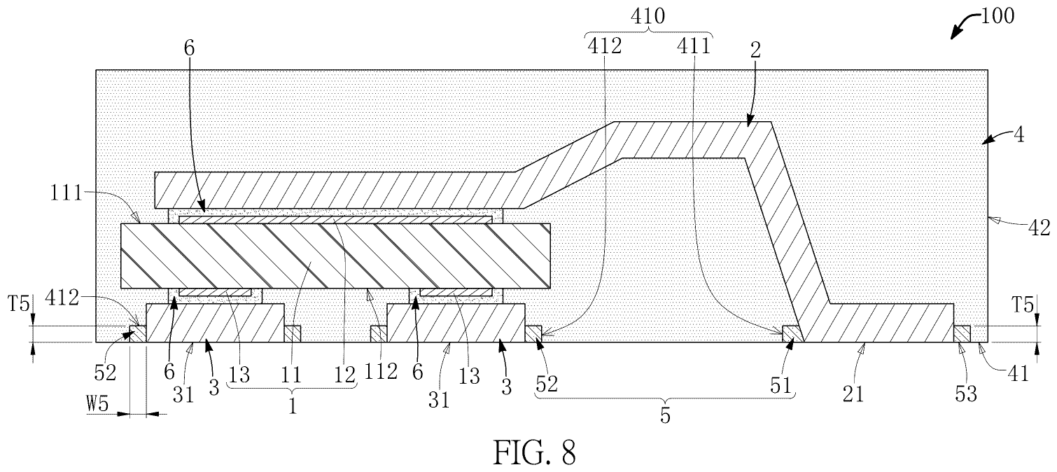

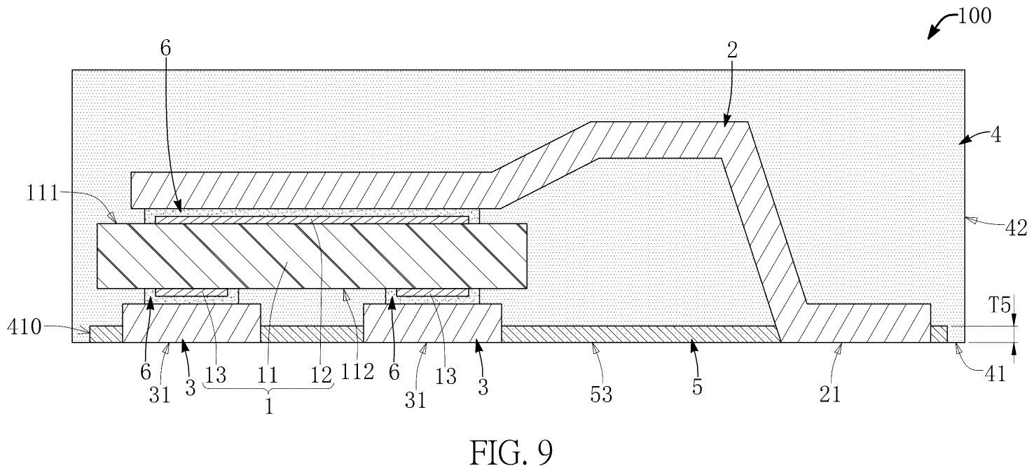

As shown in FIG. 7 to FIG. 9, the encapsulant 4 in the present embodiment includes at least one slot 410 that is recessed in the layout surface 41, and a part of the first transmission member 2 and a part of each of the two second transmission members 3 are arranged in the at least one slot 410. A formation manner of the at least one slot 410 can be adjusted or changed according to practical requirements. For example, the at least one slot 410 can be formed in a chemical etching manner, a dry plasma etching manner, or a laser etching manner. Moreover, a quantity of the at least one slot 410 can be adjusted or changed according to practical requirements. For example, the quantity of the at least one slot 410 can be one (as shown in FIG. 9) or more than one (as shown in FIG. 7 and FIG. 8).

Specifically, the DLC layer 5 is formed in the at least one slot 410 and surrounds the part of the first transmission member 2 and the part of each of the two second transmission members 3, and an outer end surface 53 (i.e., a bottom surface) of the DLC layer 5 is coplanar with the first end surface 21 and the two second end surfaces 31. The first end surface 21 is spaced apart from an adjacent one of the two second end surfaces 31 by a clearance distance that is defined along a part of the outer end surface 53 of the DLC layer 5.

Accordingly, the power chip package structure 100 of the present embodiment is provided with the DLC layer 5 that has no carbonization issue and that is cooperated with the first end surface 21 and the two second end surfaces 31, such that the power chip package structure 100 only needs to meet requirements of the clearance distance and does not need to consider creepage distance, thereby reducing limitations of the structural design of the power chip package structure. In addition, the first end surface 21 and the two second end surfaces 31 in the present embodiment are preferably coplanar with the layout surface 41, thereby facilitating the power chip package structure 100 to be applied in specific assembling processes where adverse effects on bonding due to the protruding structure around soldering pads (or the first end surface 21 and the two second end surfaces 31) can be easily eliminated.

Specifically, as shown in FIG. 7 and FIG. 8, a quantity of the at least one slot 410 is at least three, and the three slots 410 include a first slot 411 and two second slots 412. The first slot 411 surrounds the part of the first transmission member 2, and a part of the DLC layer 5 filled in the first slot 411 is defined as a first ring 51. Moreover, the two second slots 412 respectively surround the parts of the two second transmission members 3, and parts of the DLC layer 5 respectively filled in the two second slots 412 are each defined as a second ring 52.

In the present embodiment, the first ring 51 and the two second rings 52 are spaced apart from each other. Each of the first ring 51 and the two second rings 52 has a thickness T5 being within a range from 3 μm to 20 μm and a width W5 that is within a range from 5 μm to 1000 μm. Accordingly, the first transmission member 2 and the two second transmission members 3 of the power chip package structure 100 provided by the present embodiment can rapidly dissipate heat through the DLC layer 5.

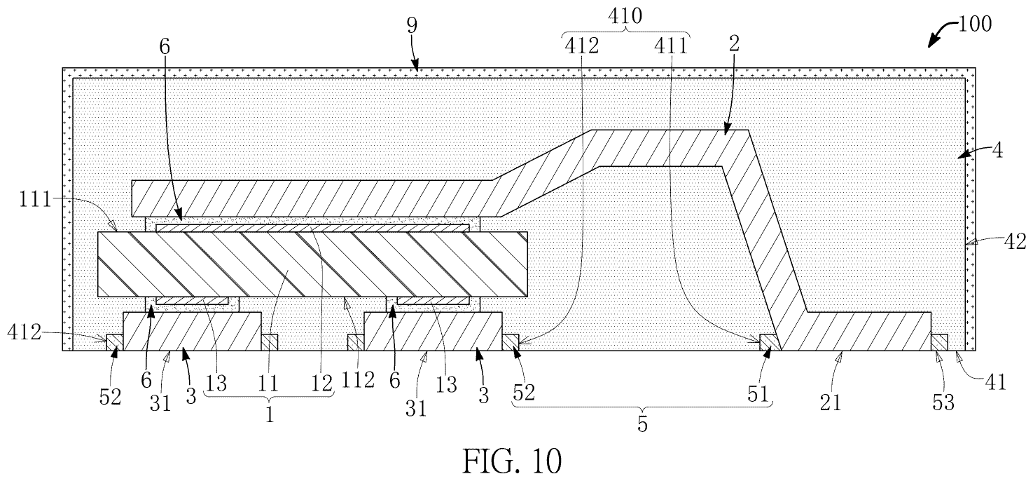

In addition, as shown in FIG. 10, the power chip package structure further includes an electrical protection layer 9 that is formed on the outer surface 42 of the encapsulant 4 and that is made of a DLC material. The electrical protection layer 9 is not in contact with the DLC layer 5, and a resistivity of the electrical protection layer 9 is less than a resistivity of the DLC layer 5. In the present embodiment, the resistivity of the electrical protection layer 9 is preferably less than 10¹⁰ ohm-cm, and a resistivity of the DLC layer 5 is preferably greater than 10¹⁰ ohm-cm.

Accordingly, the power chip package structure 100 in the present embodiment is provided with an ESD function and an EMI function by forming the electrical protection layer 9, thereby meeting more electrical requirements.

### Beneficial Effects of the Embodiments

In conclusion, the power chip package structure of the present disclosure is provided with the DLC layer that has no carbonization issue and that is cooperated with the first end surface and the two second end surfaces, such that the power chip package structure only needs to meet requirements of the clearance distance and does not need to consider creepage distance, thereby reducing limitations on the structural design of the power chip package structure.

Moreover, the first transmission member and the two second transmission members of the power chip package structure provided by the present disclosure can rapidly dissipate heat through the DLC layer, and when the power chip package structure is soldered onto a circuit board to make the first solder-receiving slot and the two second solder-receiving slots to accommodate solders, the DLC layer can not only increase wetting areas of the solders, but also forms protection walls on lateral sides of the solders that are formed with IMC, thereby preventing the IMC from having stress concentration and cracks. Accordingly, product yield, reliability, and heat-dissipation performance of the power chip package structure can be effectively improved.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A power chip package structure, comprising:
a power chip including:
a chip body having a first surface and a second surface that is opposite to the first surface;
a first bonding pad formed on the first surface; and
at least two second bonding pads formed on the second surface and spaced apart from each other;
a first transmission member connected to the first bonding pad, wherein the first transmission member has a first end surface that is arranged away from the first bonding pad;
at least two second transmission members respectively connected to the at least two second bonding pads, wherein each of the at least two second transmission members has a second end surface that is arranged away from the corresponding second bonding pad;
an encapsulant, wherein the power chip, the first transmission member, and the at least two second transmission members are embedded in the encapsulant, and wherein the encapsulant has a layout surface that is coplanar with the first end surface of the first transmission member and the second end surfaces of the two second transmission member; and
a diamond-like carbon (DLC) layer formed on the layout surface, wherein the DLC layer surrounds the first end surface to jointly define a first solder-receiving slot, and the DLC layer surrounds each of the two second end surfaces to jointly define a second solder-receiving slot;
wherein the first end surface is spaced apart from an adjacent one of the two second end surfaces by a clearance distance that is defined along the first solder-receiving slot, the corresponding second solder-receiving slot, and a part of an outer end surface of the DLC layer.

2. The power chip package structure according to claim 1, wherein the DLC layer covers an entirety of the layout surface of the encapsulant.

3. The power chip package structure according to claim 1, wherein the DLC layer covers a peripheral region of the first end surface having a width that is within a range from 5 μm to 100 μm, and the DLC layer covers a peripheral region of each of the two second end surfaces having a width that is within a range from 5 μm to 100 μm.

4. The power chip package structure according to claim 1, wherein a thickness of the DLC layer is within a range from 3 μm to 20 μm, and a resistivity of the DLC layer is greater than 10¹⁰ ohm-cm.

5. The power chip package structure according to claim 1, wherein the encapsulant has an outer surface connected to a peripheral edge of the layout surface, and the power chip, the first transmission member, and the at least two second transmission members are located in a region surrounded by the outer surface of the encapsulant, wherein the power chip package structure further includes an electrical protection layer that is formed on the outer surface of the encapsulant and that is made of a DLC material, and wherein the electrical protection layer is not in contact with the DLC layer, and a resistivity of the electrical protection layer is less than a resistivity of the DLC layer.

6. The power chip package structure according to claim 5, wherein the resistivity of the electrical protection layer is less than 10¹⁰ ohm-cm, and a resistivity of the DLC layer is greater than 10¹⁰ ohm-cm.

7. The power chip package structure according to claim 1, wherein the first transmission member is a lead frame, one end of the lead frame has the first end surface, and another end of the lead frame is connected to the first bonding pad, and wherein each of the at least two second transmission members is a metal block, and the at least two second transmission members are respectively connected to the at least two second bonding pads.

8. The power chip package structure according to claim 1, further comprising a ceramic board embedded in the encapsulant, an inner metal layer formed on the ceramic board, and an extending metal block that is connected to one end of the inner metal layer, wherein the inner metal layer and the extending metal block are jointly defined as the first transmission member, the extending metal block has the first end surface, and another end of the extending metal block is connected to the first bonding pad, and wherein each of the at least two second transmission members is a metal block, and the at least two second transmission members are respectively connected to the at least two second bonding pads.

9. The power chip package structure according to claim 8, further comprising an outer metal layer, wherein the inner metal layer and the outer metal layer are respectively electrically bonded to two opposite surfaces of the ceramic board, and a surface of the outer metal layer arranged away from the inner metal layer is exposed from the encapsulant.

10. The power chip package structure according to claim 1, further comprising a plurality of conductive pastes, wherein the first transmission member is electrically bonded to the first bonding pad through one of the conductive pastes, and each of the at least two second transmission members is sintered to the corresponding second bonding pad through one of the conductive pastes.

11. The power chip package structure according to claim 1, wherein the first bonding pad is a drain pad, and the at least two second bonding pads are a source pad and a gate pad, respectively.

12. A power chip package structure, comprising:
a power chip including:
a chip body having a first surface and a second surface that is opposite to the first surface;
a first bonding pad formed on the first surface; and
at least two second bonding pads formed on the second surface and spaced apart from each other;
a first transmission member connected to the first bonding pad, wherein the first transmission member has a first end surface that is arranged away from the first bonding pad;
at least two second transmission members respectively connected to the at least two second bonding pads, wherein each of the at least two second transmission members has a second end surface that is arranged away from the corresponding second bonding pad;
an encapsulant, wherein the power chip, the first transmission member, and the at least two second transmission members are embedded in the encapsulant, wherein the encapsulant has a layout surface and at least one slot that is recessed in the layout surface, and wherein a part of the first transmission member and a part of each of the at least two second transmission members are arranged in the at least one slot; and
a diamond-like carbon (DLC) layer formed in the at least one slot and surrounding the part of the first transmission member and the part of each of the at least two second transmission members, wherein an outer end surface of the DLC layer is coplanar with the first end surface and the two second end surfaces;
wherein the first end surface is spaced apart from an adjacent one of the two second end surfaces by a clearance distance that is defined along a part of the outer end surface of the DLC layer.

13. The power chip package structure according to claim 12, wherein the first end surface and the two second end surfaces are coplanar with the layout surface, a quantity of the at least one slot is three, and the three slots include:
a first slot surrounding the part of the first transmission member, wherein a part of the DLC layer filled in the first slot is defined as a first ring; and
two second slots respectively surrounding the parts of the at least two second transmission members, wherein parts of the DLC layer respectively filled in the two second slots are each defined as a second ring, and wherein the first ring and the two second rings are spaced apart from each other.

14. The power chip package structure according to claim 13, wherein each of the first ring and the two second rings has a thickness being within a range from 3 μm to 20 μm and a width that is within a range from 10 μm to 1000 μm.

15. The power chip package structure according to claim 12, wherein the encapsulant has an outer surface connected to a peripheral edge of the layout surface, and the power chip, the first transmission member, and the at least two second transmission members are located in a region surrounded by the outer surface of the encapsulant, wherein the power chip package structure further includes an electrical protection layer that is formed on the outer surface of the encapsulant and that is made of a DLC material, and wherein the electrical protection layer is not in contact with the DLC layer, and a resistivity of the electrical protection layer is less than a resistivity of the DLC layer.
